(19) United States
(12) Patent Application Publication
(10) Pub. No.: US 2025/0098161 A1
(43) Pub. Date: Mar. 20, 2025

(54) MEMORY DEVICE AND METHOD OF MANUFACTURING THE SAME

(71) Applicant: SK hynix Inc., Icheon-si Gyeonggi-do (KR)

(72) Inventor: Yun Cheol HAN, Icheon-si Gyeonggi-do (KR)

(73) Assignee: SK hynix Inc., Icheon-si Gyeonggi-do (KR)

(21) Appl. No.: 18/605,484

(22) Filed: Mar. 14, 2024

(30) Foreign Application Priority Data
Sep. 15, 2023 (KR) 10-2023-0122816

(51) Int. Cl. H10B 43/20; H01L 21/027; H10B 43/40

(52) U.S. Cl. CPC H10B 43/20; H01L 21/0274; H10B 43/40

(57) ABSTRACT

Provided herein is a method of manufacturing a memory device. The method may include forming an ion implantation region in a portion of an outer portion of an underlying structure by implanting ions into the underlying structure, transforming the ion implantation region into an etch stop pattern, forming a target structure on the underlying structure including the etch stop pattern, and performing an etching process to form first holes and second holes in the target structure, wherein the first width of the first holes is different than the second width of the second holes. The etching process is performed until the etch stop pattern is exposed through the first holes and the second holes.

### CROSS-REFERENCE TO RELATED APPLICATION

The present application claims priority under 35 U.S.C. § 119(a) to Korean patent application number 10-2023-0122816 filed on Sep. 15, 2023, in the Korean Intellectual Property Office, the entire disclosure of which is incorporated herein by reference.

### BACKGROUND

### 1. Technical Field

Various embodiments of the present disclosure generally relate to a memory device and a method of manufacturing the same, and more particularly to a three-dimensional (3D) memory device.

### 2. Related Art

A memory device may include a memory cell array in which data is stored, peripheral circuits configured to perform program, read, and erase operations for the memory cell array, and a control circuit configured to control the peripheral circuits.

The memory cell array may include a plurality of memory blocks, and each of the memory blocks may include a plurality of memory cells.

In order to increase the data storage capacity of the memory device and reduce the size of the memory device, the integration degree of memory devices is gradually increasing.

In a conventional memory device, memory cells are arranged in a direction parallel to a substrate. Nevertheless, due to physical limitations in increasing the integration degree, the memory cells are manufactured in a structure in which the memory cells are stacked in a vertical direction from the substrate. A conventional structure in which the memory cells are arranged in a direction parallel to the substrate is referred to as a two-dimensional (2D) structure, while a structure in which the memory cells are stacked in a direction perpendicular to the substrate is referred to as a three-dimensional (3D) structure.

Memory devices having the three-dimensional structure may include a cell region containing the memory cells and a peripheral region containing a peripheral circuit for operating the memory cells. Because structures included in the cell region and the peripheral circuit region may perform different functions, the structures may have different sizes. For example, the width of cell plugs included in the cell region may be different from the width of contacts or support structures included in the peripheral region. The memory device may include vertical structures that perform various functions, in addition to the cell plugs, the contacts, and the support structures.

In order to form the vertical structures, an etching process for forming a vertical hole may be performed. For example, the etching process may be an anisotropic dry etching process that may be performed to form the vertical hole. During the anisotropic dry etching process, the bottom of a target structure is removed by an etchant. As the width of the vertical hole increases, an area contacting the etchant increases, thus causing a difference in etching rate. For example, the depth of the vertical hole may vary depending on the width of the vertical hole.

### SUMMARY

An embodiment of the present disclosure may provide for a method of manufacturing a memory device. The method may include forming an ion implantation region in a portion of an outer portion of an underlying structure by implanting ions into the underlying structure, transforming the ion implantation region into an etch stop pattern, forming a target structure on the underlying structure including the etch stop pattern, and performing an etching process to form first holes and second holes in the target structure, wherein a first width of the first holes is different than a second width of the second holes. The etching process may be performed until the etch stop pattern is exposed through the first holes and the second holes.

An embodiment of the present disclosure may provide for a method of manufacturing a memory device. The method may include forming an ion implantation region in a portion of an outer portion of a first underlying structure, performing a heat treatment process for changing the ion implantation region into an etch stop pattern, alternately stacking first material layers and second material layers on the first underlying structure including the etch stop pattern, and forming, in the first and second material layers, a first hole that exposes a first portion of the etch stop pattern, wherein the first hole has a first width, and a second hole that exposes a second portion of the etch stop pattern, wherein the second hole has a second width greater than the first width.

An embodiment of the present disclosure may provide for a memory device comprising an underlying structure including a first etch stop pattern and a second etch stop pattern; and a target structure formed over the underlying structure, wherein a first hole having a first aspect ratio and a second hole having a second aspect ratio less than the first aspect ratio are formed in the target structure, wherein the first etch stop pattern is exposed by the first hole and the second etch stop pattern is exposed by the second hole; wherein the first etch stop pattern and the second etch stop pattern include etching stop ions for stopping an etching process; and wherein the second etch stop pattern includes a region having a high concentration of etching stop ions and a region having a low concentration of etching stop ions.

An embodiment of the present disclosure may provide for a method of manufacturing a memory device. The method may include forming a target structure over an underlying structure; forming a mask pattern over the target structure; implanting etching stop ions into the underlying structure through the target structure using the mask patterns to form a first etch stop pattern and a second etch stop pattern; and etching the target structure using the mask pattern until the first etch stop pattern is exposed to form a first hole with a first aspect ratio and etching the target structure until the second etch stop pattern is exposed to form a second hole with a second aspect ratio less than the first aspect ratio; wherein, when the etch stop ions are implanted, the second etch stop pattern includes a region having a high concentration of etching stop ions and a region having a low concentration of etching stop ions.

### BRIEF DESCRIPTION OF THE DRAWINGS

FIG. 1 illustrates views of a memory device formed utilizing a conventional method of manufacturing the memory device.

FIG. 2 through FIG. 7 illustrate various views of a memory device formed utilizing a method of manufacturing the memory device according to a first embodiment of the present disclosure.

FIG. 8 is a diagram illustrating a memory device in accordance with embodiments of the present disclosure.

FIG. 9 is a diagram illustrating memory blocks included in the memory device in accordance with embodiments of the present disclosure.

FIG. 10 through FIG. 20 illustrate additional views of a memory device formed utilizing a method of manufacturing the memory device according to the first embodiment.

FIG. 21 through FIG. 26 illustrate various views of a memory device formed utilizing a method of manufacturing the memory device according to a second embodiment of the present disclosure.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments that will be described later and may be modified in various forms and replaced with other equivalent embodiments.

Although terms such as “first” and “second” may be used herein to describe various elements, the elements are not limited by these terms. The terms are used to distinguish one element from other elements and do not imply size, order, priority, or importance. Terms such as “top” or “bottom” or “above” or “below” or “over” or other terms implying spatial relationship are provided only for the purpose of ease of description or reference and are not otherwise limiting.

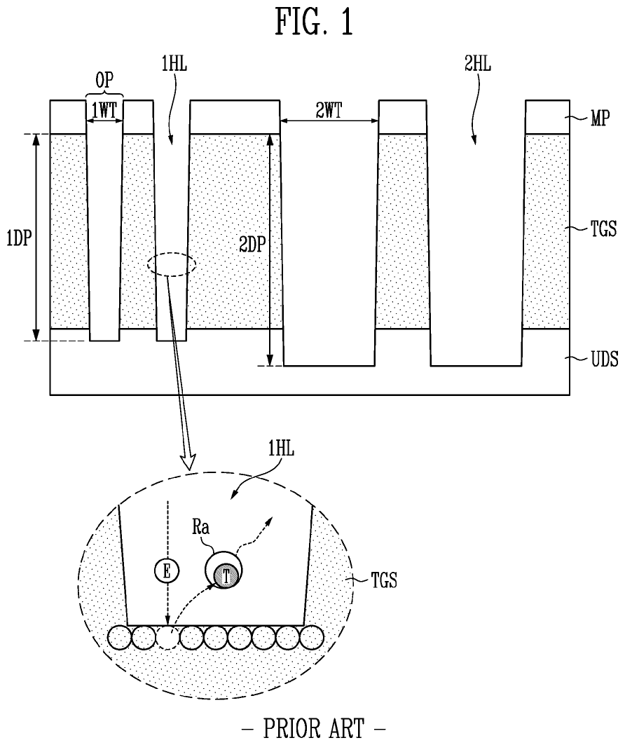

FIG. 1 illustrates views of a memory device formed utilizing a conventional method of manufacturing the memory device.

Referring to the example of FIG. 1, a target structure TGS is formed on an underlying structure UDS, and a mask pattern MP is formed on a target structure TGS. The mask pattern MP includes openings OP that expose a portion of a top or outer surface of the target structure TGS. For example, each of the openings OP corresponding to first holes 1HL may have a first width 1WT, and each of the openings OP corresponding to second holes 2HL may have a second width 2WT that is greater than the first width 1WT. In an embodiment, each of the first holes 1HL and the second holes 2HL may have a circular, elliptical, or line shape, for example.

The etching process may be an anisotropic dry etching process that may be performed to simultaneously form the first holes 1HL and the second 2HL. During the anisotropic dry etching process, etchant ions E may collide in a direction perpendicular to the bottom surface of the target structure TGS exposed through the openings OP of the mask pattern MP. When the etchant ions E contact the target structure TGS, atoms or molecules of the target structure TGS may be separated from a body of the target structure TGS by physical impact or chemical change. Target ions T separated from the target structure TGS may be combined with radicals Ra and be discharged outside of a chamber.

Because a difference in area at the bottom surface is exposed by the first holes 1HL and second holes 2HL, a difference may also occur in the depth of the first holes 1HL and second holes 2HL during the etching process. For example, because the second hole 2HL has a second width 2WT that is greater than a first width 1WT of the first hole 1HL, the etching rate of the second hole 2HL may be greater than the etching rate of the first hole 1HL. For this reason, when the etching process is performed until the underlying structure UDS is exposed through the first and second holes 1HL and 2HL, a difference in depth may occur. For example, when the first hole 1HL has the first depth 1DP, the second hole 2HL may have a second depth 2DP that is deeper than the first depth 1DP. The depth refers to a length or distance from the top surface or uppermost surface (with respect to the drawing perspective) of the target structure TGS to the bottom or lowermost surface (with respect to the drawing perspective) of the first hole 1HL or the second hole 2HL.

After the first and second holes 1HL and 2HL having different depths 1DP and 2DP are formed, the first and second holes 1HL and 2HL are filled with a gap-fill material, and a process of removing the underlying structure UDS is performed. The gap-fill material in the second hole 2HL is initially exposed to the etching process and as the etching process continues, the gap-fill material in the first hole 1HL is exposed. In this example, etching damage to the gap-fill material in the second hole 2HL increases as the etching process continues to expose the gap-fill material in the first hole 1HL.

In various embodiments described below, a method of manufacturing the memory device allows holes of different widths to have the same depth. Various embodiments are directed to methods of manufacturing a memory device, which methods may advantageously reduce defects in the memory device.

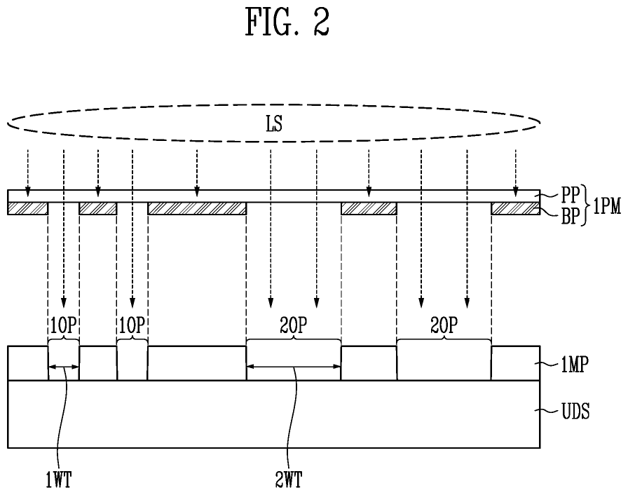

FIG. 2 through FIG. 7 illustrate various views of a memory device formed utilizing a method of manufacturing the memory device according to a first embodiment of the present disclosure.

Referring to FIG. 2, a first mask pattern 1MP may be formed on the underlying structure UDS. The underlying structure UDS may be a substrate. For example, the substrate may be an N-type or P-type silicon substrate. The first mask pattern 1MP may be a photoresist pattern or may include a hard mask pattern and a photoresist pattern stacked on the hard mask pattern. For example, the hard mask pattern may be a mask layer formed of carbon. In order to form the photoresist pattern of the first mask pattern 1MP, exposure and development processes using the first photo mask 1PM may be performed.

For example, a photoresist layer may be formed on the underlying structure USD or the hard mask layer, and the exposure and development processes using the first photo mask 1PM may be performed. The first photo mask 1PM may include a transmission plate PP and a blocking pattern BP. For example, the transmission plate PP may be a glass plate, and the blocking pattern BP may be formed of chromium. The first photo mask 1PM is not limited to the above-described materials. First openings 1OP and second openings 2OP are formed in the blocking pattern BP, where the first openings 1OP have widths 1WT different than the widths 2WT of the second openings 2OP. When the exposure process is performed, a light source LS may not penetrate the blocking pattern BP and may irradiate the photoresist layer through the first openings 1OP and the second openings 2OP. Portions of the photoresist layer irradiated by the light source LS may be removed during the development process. Thus, the first mask pattern 1MP is formed including forming the first openings 1OP and the second openings 2OP in the first mask pattern 1MP. When the hard mask layer is formed under the photoresist layer, an etching process may be further performed to remove a portion of the hard mask layer exposed through the first and second openings 1OP and 2OP after the first and second openings 1OP and 2OP are formed in the photoresist layer.

In the first mask pattern 1MP, each of the first openings 1OP is formed with a first width 1WT and each of the second openings 2OP is formed with a second width 2WT that is greater (larger) than the first width 1WT. In this example, the area of the underlying structure UDS exposed through the first openings 1OP of the first mask pattern 1MP is smaller than the area of the underlying structure UDS exposed through the second openings 2OP.

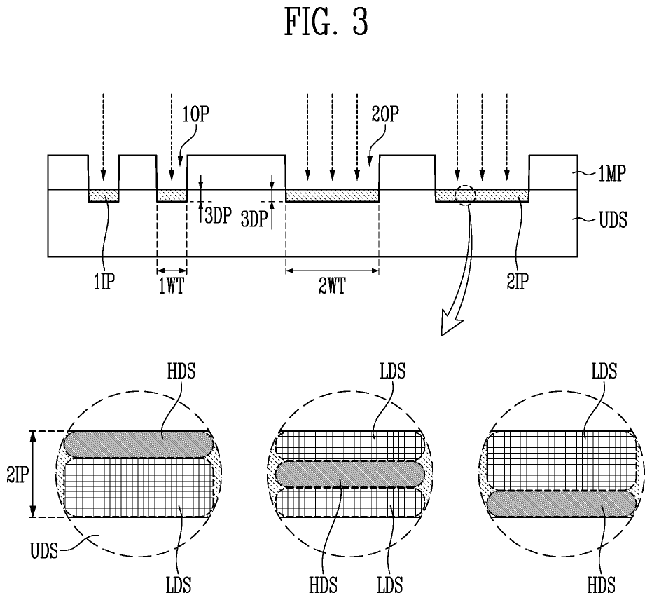

Referring to FIG. 3, an ion implantation process may be performed to form a first ion implantation region 1IP and a second ion implantation region 2IP in the underlying structure UDS, which regions are exposed through the first openings 1OP and the second openings 2OP, respectively, of the first mask pattern 1MP. For example, the ion implantation process may be performed by implanting ions, such as etching stop ions, of a material different from the material that is to be formed on the underlying structure UDS. For example, the ion implantation process may be performed by implanting nitrogen ions into regions of the underlying structure UDS exposed through the first openings 1OP and the second openings 2OP. The first ion implantation regions 1IP and the second ion implantation regions 2IP of the underlying structure UDS into which nitrogen ions are implanted may be an amorphous silicon nitride layer (SixNy; where x and y are positive integers). Each of the first ion implantation regions 1IP may have the same first width 1WT as the width of each of the first openings 1OP. Each of the second ion implantation regions 2IP may have the same second width 2WT as the width of each of the second openings 2OP. Each of the first ion implantation regions 1IP and the second ion implantation regions 2IP may have a third depth 3DP. The third depth 3DP is a length or distance from the top, upper, or outermost surface (with respect to the drawing perspective) of the underlying structure UDS to the lowest surface where ions are implanted. The third depth 3DP may be adjusted depending on various conditions of the ion implantation process. For example, the third depth 3DP may be adjusted depending on the type of gas supplied into the chamber, the amount of gas, the movement speed of ionized positive ions, and/or temperature inside the chamber during the ion implantation process.

The first ion implantation regions 1IP and the second ion implantation regions 2IP are formed along an outer or top surface (with respect to the drawing perspective) of the underlying structure UDS to the third depth 3DP, but an ion implantation concentration within the third depth 3DP may vary. For example, the concentration of nitrogen ions may vary within the ion implantation regions depending on the depth. By adjusting ion implantation energy during the ion implantation process, a high concentration region HDS of ions and a low concentration region LDS of ions may result, and the concentrations of ions may be varied within the ion implantation regions. The high concentration regions HDS have a higher concentration of etching stop ions than the low concentration regions LDS, in other words, the low concentration regions LDS have a lower concentration of etching stop ions than the high concentration regions HDS. Taking the second ion implantation region 2IP as an example, the second ion implantation region 2IP includes the high concentration region HDS located at the outer (exposed) or upper portion of the second ion implantation region 2IP within the underlying structure UDS, and the low concentration region LDS located under or below (with respect to the drawing perspective) the high concentration region HDS, i.e., inside or away from the exposed outer perimeter, such as shown in the left section view at the bottom of FIG. 3. In another example, the second ion implantation region 2IP may include the low concentration regions LDS located at the outer (outermost) or upper portions and innermost (farthest from the exposed outer perimeter second ion implantation region 2IP of the underlying structure UDS) or lower portions of the second ion implantation region 2IP within the underlying structure UDS and may include the high concentration region HDS located between the low concentration regions LDS, such as shown in the middle section view at the bottom of FIG. 3. In a further example, the second ion implantation region 2IP may include the low concentration region LDS at the outer (exposed) or upper portion of the second ion implantation region 2IP within the underlying structure UDS and may include the high concentration region HDS located under or below (with respect to the drawing perspective) the low concentration region LDS, i.e., inside or away from the exposed outer perimeter, such as shown in the right section view at the bottom of FIG. 3. Etch stop may be more efficiently achieved in the high concentration region HDS than in the low concentration region LDS.

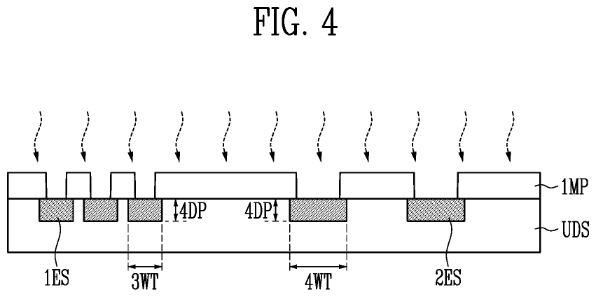

Referring to FIG. 4, a heat treatment process is performed to recrystallize the underlying structure UDS of each of the first ion implantation regions 1IP and the second ion implantation regions 2IP (see FIG. 3). The silicon nitride layers of the first ion implantation regions 1IP and the second ion implantation regions 2IP (see FIG. 3) recrystallized by the heat treatment process serve as first etch stop patterns 1ES and second etch stop patterns 2ES, respectively. For example, the first ion implantation regions 1IP (see FIG. 3) become first etch stop patterns 1ES, while the second ion implantation regions 2IP (see FIG. 3) become second etch stop patterns 2ES. Thus, the heat treatment process transforms or changes the ion implantation regions into etch stop patterns, which process may be referred to as activating the ion implantation regions.

During the heat treatment process, the ions implanted into the first and second ion implantation regions 1IP and 2IP diffuse into the underlying structure UDS, such that the first etch stop patterns 1ES may be larger in size than the first ion implantation regions 1IP, and the second etch stop patterns 2ES may also be larger in size than the second ion implantation regions 2IP. For example, each of the first etch stop patterns 1ES may have a third width 3WT that is greater than the first width 1WT (see FIG. 3), and each of the second etch stop patterns 2ES may have a fourth width 4WT that is greater than the second width 2WT (see FIG. 3). The first and second etch stop patterns 1ES and 2ES may have a fourth depth 4DP that is deeper than the depths of the first ion implantation regions 1IP and the second ion implantation regions 2IP. The first stop patterns 1ES and the second etch stop patterns 2ES may have the same depth but may have different depths depending on the concentration of ions implanted in the first ion implantation regions 1IP and the second ion implantation regions 2IP.

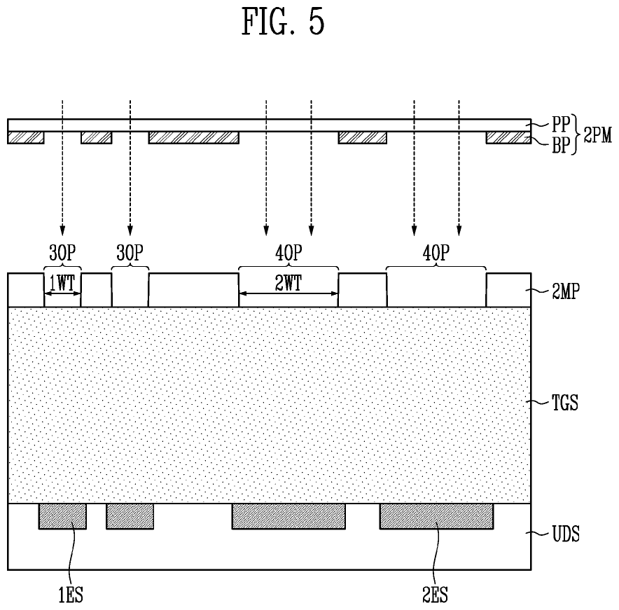

Referring to FIG. 5, the target structure TGS and a second mask pattern 2MP may be sequentially stacked on the underlying structure UDS including the first etch stop patterns 1ES and the second etch stop patterns 2ES. For example, the target structure TGS may be formed of a single layer or multiple layers. In the first embodiment, the type and number of materials forming the target structure TGS are not limited to a specific type and number.

The second mask pattern 2MP may be composed of a photoresist pattern or may be composed of a hard mask pattern and a photoresist pattern stacked on the hard mask pattern. For example, the hard mask pattern may be a mask layer formed of carbon. In order to form the photoresist pattern of the second mask pattern 2MP, the exposure and development processes using the second photo mask 2PM may be performed. The second photo mask 2PM may be the same as the first photo mask 1PM described with reference to FIG. 2 above. When the exposure and development processes using the second mask pattern 2MP are performed, the second mask pattern 2MP is formed, including forming the third openings 3OP and fourth openings 4OP in the second mask pattern 2MP.

In the second mask pattern 2MP, each of the third openings 3OP is formed with the first width 1WT, and each of the fourth openings 4OP is formed with the second width 2WT that is greater than the first width 1WT in this example. In this example, the area of the target structure TGS exposed through the third openings 3OP of the second mask pattern 2MP is smaller than the area of the target structure TGS exposed through the fourth openings 4OP.

In various embodiments, the target structure TGS may be formed on the underlying structure UDS when the first etch stop patterns 1ES and the second etch stop patterns 2ES are not yet formed. The second mask patten 2MP (or the first mask pattern 1MP) may be formed on the target structure TGS to expose areas where the first holes 1OP and the second holes 2OP will be formed. The ions for stopping etching in the target structure TGS, i.e., etch stop ions, may be implanted in the top or outer surface of the underlying structure UDS by adjusting implantation energy, for example, at a projected depth past the target structure and into the underlying structure UDS. The etch stop ions may be implanted through the target structure. For example, the etch stop ions may be nitrogen ions. The projected depth of the etch stop ions and the concentration of the etch stop ions may be controlled or adjusted based on aspect ratios of the first holes 1OP and the second holes 2OP or heights and/or widths of the first holes 1OP and the second holes 2OP. The etch stop ions may be activated by heat treatment, such as an annealing process, to form the first etch stop pattern 1ES and the second etch stop pattern 2ES.

For example, when the first hole 1OP has a first aspect ratio and the second hole 2OP has a second aspect ratio less than the first aspect ratio, a concentration of the etch stop ions in the first etch stop pattern 1ES to be exposed by the first hole 1OP may be uniform, but a concentration of the etch stop ions of the second etch stop pattern 2ES may vary depending on a depth (or thickness) of the second etch stop pattern 2ES. For example, the second etch stop pattern 2ES may include a high concentration region HDS of etch stop ions and a low concentration region LDS of etch stop ions, such as shown in the section views in FIG. 3. The high concentration region may be positioned in any of an upper portion, a lower portion, and a middle portion between the upper portion and lower portion of the second etch stop pattern 2ES. An advantage of placing the high concentration region HDS at various positions, layers, or levels in the second etch stop pattern 2ES is to provide control by selectively reducing over-etching. Considering the aspect ratios of the first holes 1OP and the second holes 2OP and an over-etching degree of a bottom region of each of the first holes 1OP and the second holes 2OP, a position of the high concentration region HDS of the second etch stop pattern 2ES may be determined. The aspect ratio of a hole (or a pattern) may be the ratio of its width to its height.

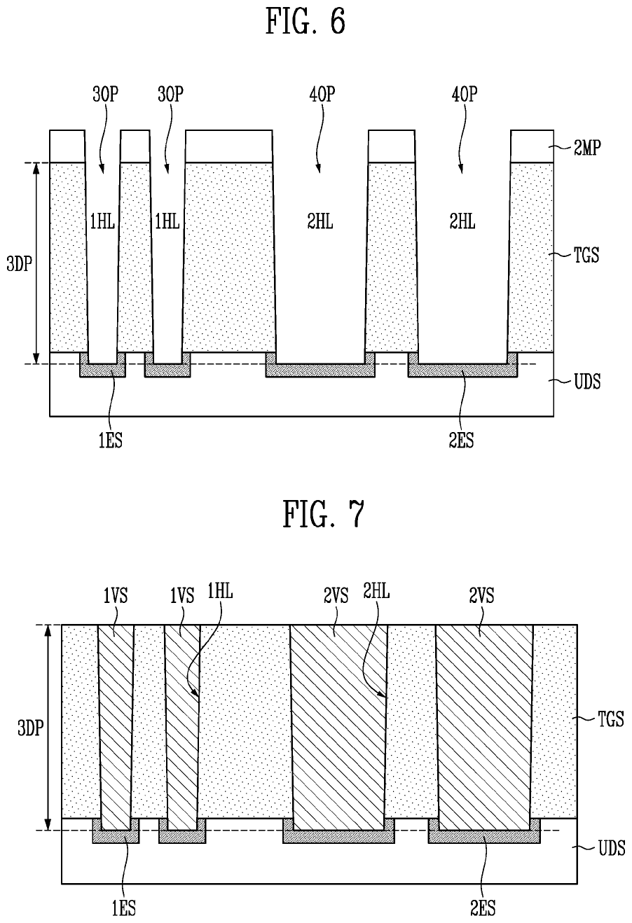

Referring to FIG. 6, the etching process may be performed to form the first holes 1HL and the second holes 2HL in the target structure TGS exposed through the third openings 3OP and fourth openings 4OP of the second mask pattern 2MP. The etching process may be an anisotropic dry etching process. Because the area exposed through the fourth openings 4OP is larger than the area exposed through the third openings 3OP during the etching process of the target structure TGS, the second holes 2HL may be formed to be deeper depth than the first holes 1HL, in other words, the second holes 2HL may be formed with a height higher than the height of the first holes 1HL as formed.

Thus, the second etch stop pattern 2ES may be exposed through the second holes 2HL before the first etch stop patterns 1ES are exposed through the first holes 1HL. Therefore, during the etching process for forming the first holes 1HL at the third depth 3DP, which is the target depth, an increase in the depth, beyond the target depth, of the second holes 2HL may be prevented. The etching process may be performed until the first etch stop patterns 1ES and the second etch stop patterns 2ES are exposed through the first holes 1HL and the second holes 2HL, respectively.

Referring to FIG. 7, gap-fill layers may be filled in the first holes 1HL and the second holes 2HL to form first vertical structures 1VS and second vertical structures 2VS that contact the first etch stop patterns 1ES and the second etch stop patterns 2ES. The first vertical structures 1VS and the second vertical structures 2VS may be formed of the same material to provide the same structure or be formed of different materials to provide different structures. For example, the first vertical structures 1VS may be formed in the first holes 1HL, and the second vertical structures 2VS may be formed in the second holes 2HL. The first vertical structures 1VS and second vertical structures 2VS may be formed having the third depth 3DP by the first etch stop patterns 1ES and the second etch stop patterns 2ES.

A method of manufacturing the memory device according to the first embodiment using the above-described manufacturing method is described as follows.

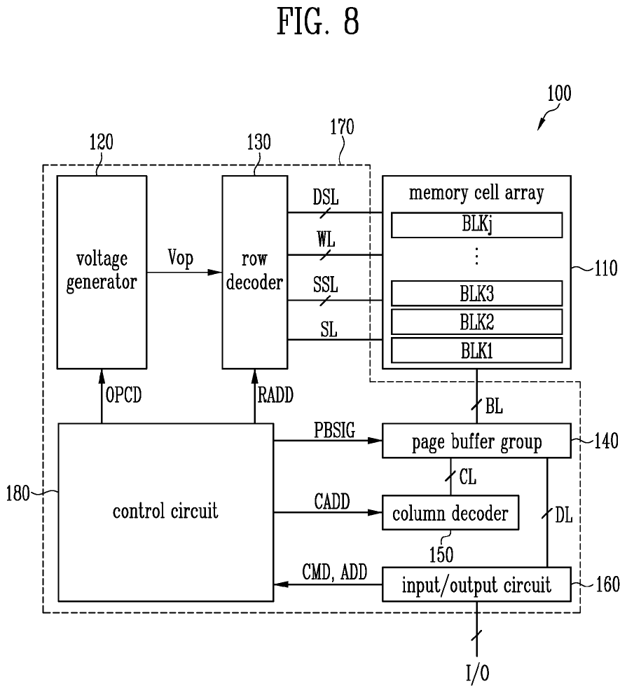

FIG. 8 is a diagram illustrating a memory device in accordance with the embodiments of the present disclosure described herein.

Referring to FIG. 8, a memory device 100 may include a memory cell array 110 and peripheral circuits 170.

The memory cell array 110 may include first to j-th memory blocks BLK1 to BLKj. Each of the first to j-th memory blocks BLK1 to BLKj may include memory cells that are capable of storing data. Drain select lines DSL, word lines WL, source select lines SSL, and a source line SL may be coupled to each of the first to j-th memory blocks BLK1 to BLKj, and bit lines BL may be coupled in common to the first to j-th memory blocks BLK1 to BLKj.

Each of the first to j-th memory blocks BLK1 to BLKj may be formed to have a three-dimensional (3D) structure. Each memory block having a 3D structure may include memory cells stacked on a substrate in a vertical direction. According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuits 170 may perform a program operation including storing data in the memory cell array 110, a read operation including outputting data stored in the memory cell array 110, and an erase operation including erasing data stored in the memory cell array 110. For example, the peripheral circuits 170 may include a voltage generator 120, a row decoder 130, a page buffer group 140, a column decoder 150, an input/output circuit 160, and a control circuit 180.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to a selected word line among the word lines WL during a program operation and may be used to increase the threshold voltages of memory cells coupled to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off drain select transistors or source select transistors. For example, the turn-off voltage may be set to 0 V. The precharge voltages may be voltages higher than 0 V and may be applied to the bit lines during a read operation. The verify voltages may be used during a verify operation including determining whether the threshold voltages of selected memory cells have increased to a target level. The verify voltages may be set to various levels according to the target level and may be applied to a selected word line. The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation and may be used to turn on memory cells coupled to the unselected word lines. The erase voltages may be used during an erase operation of erasing the memory cells included in the selected memory block and may be applied to the source line SL.

The row decoder 130 may transfer the operating voltages Vop to the drain select lines DSL, the word lines WL, the source select lines SSL, and the source line SL, which are coupled to a memory block selected according to a row address RADD. For example, the row decoder 130 may be coupled to the voltage generator 120 through global lines GL, and may be coupled to the first to j-th memory blocks BLK1 to BLKj through the drain select lines DSL, the word lines WL, the source select lines SSL, and the source line SL.

The page buffer group 140 may include page buffers (not illustrated) coupled to the first to j-th memory blocks BLK1 to BLKj, respectively. The page buffers (not illustrated) may be coupled to each of the first to j-th memory blocks BLK1 to BLKj through the bit lines BL.

The column decoder 150 may be configured such that data is transferred between the page buffer group 140 and the input/output circuit 160 in response to a column address CADD. For example, the column decoder 150 may be coupled to the page buffer group 140 through column lines CL and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output the operation code OPCD, the row address RADD, page buffer control signals PBSIG, and the column address CADD in response to the command CMD and the address ADD. For example, when the command CMD input to the control circuit 180 is a command corresponding to a program operation, the control circuit 180 may control the peripheral circuits 170 such that the program operation is performed on a memory block selected by the address ADD. When the command CMD input to the control circuit 180 is a command corresponding to a read operation, the control circuit 180 may control the peripheral circuits 170 such that the read operation is performed on a memory block selected by the address and read data is output. When the command CMD input to the control circuit 180 is a command corresponding to an erase operation, the control circuit 180 may control the peripheral circuits 170 such that the erase operation is performed on a selected memory block.

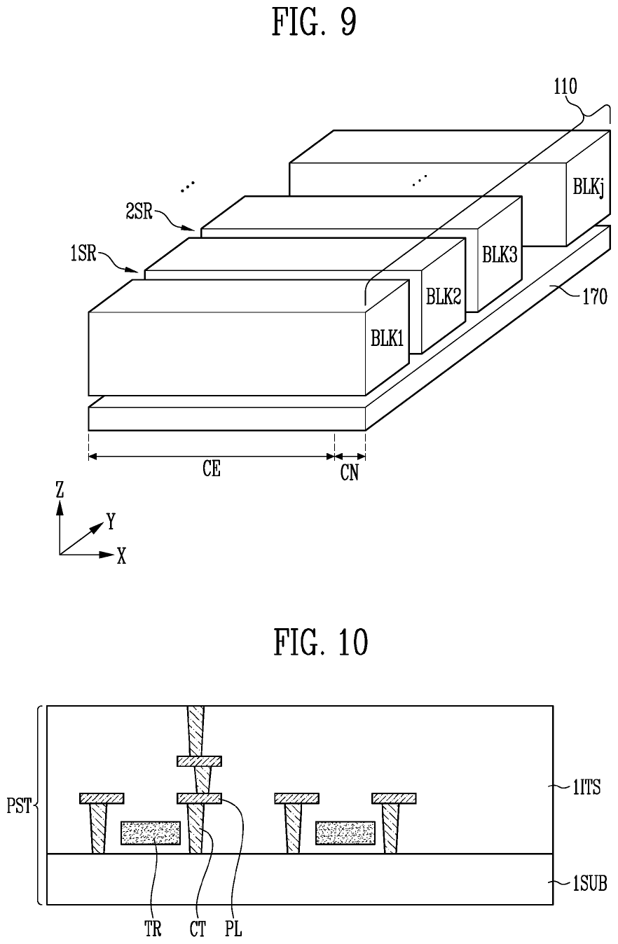

FIG. 9 is a diagram illustrating memory blocks included in the memory device in accordance with the embodiments of the present disclosure described herein.

Referring to FIG. 9, a memory cell array 110 may be located on peripheral circuits 170, but the positions of the memory cell array 110 and the peripheral circuits are not limited to the positions illustrated in FIG. 9. For example, the memory cell array 110 may be located on the same plane as the peripheral circuits 170, or the memory cell array and the peripheral circuits may be formed on different substrates and then contact each other.

The memory cell array 110 may include first to j-th memory blocks BLK1 to BLKj. The first to j-th memory blocks BLK1 to BLKj may be arranged to be spaced apart from each other a Y direction. The first to j-th memory blocks BLK1 to BLKj may be configured identically to each other, and be divided from each other by slit regions 1SR, 2SR, . . . . Each of the slit regions 1SR, 2SR, . . . may extend along an X direction. For example, the first and second memory blocks BLK1 and BLK2 may be divided from each other by the first slit region 1SR.

The first to j-th memory blocks BLK1 to BLKj may include a cell region CE and a connection region CN. The cell region CE may include memory cells, and the connection region CN may include contacts and support structures. The memory cells may be configured to store data, the contacts may be configured to contact gate lines extending from the cell region CE or to contact peripheral circuits located in the lower portion of the memory block, and the support structures may be configured to support a stacked structure located in the connection region CN.

FIG. 10 through FIG. 20 illustrate additional views of the memory device formed utilizing a method of manufacturing the memory device according to the first embodiment.

Referring to FIG. 10, a peripheral structure PST is formed. The peripheral structure PST may include at least a portion of the peripheral circuits 170 illustrated in FIG. 9. The peripheral structure PST may include a first substrate 1SUB, transistors TR formed on the first substrate 1SUB, contacts CT, and peripheral lines PL. The first substrate 1SUB may be a silicon substrate. The transistors TR may be transistors forming circuits included in the peripheral circuits 170 (see FIG. 9), and the contacts CT may be configured to electrically connect the first substrate 1SUB and the peripheral lines PL, to electrically connect the peripheral lines PL located at different layers, or to electrically connect the transistors TR and the peripheral lines PL. A first interlayer insulator 1ITS may be filled between the transistors TR, the contacts CT, and the peripheral lines PL.

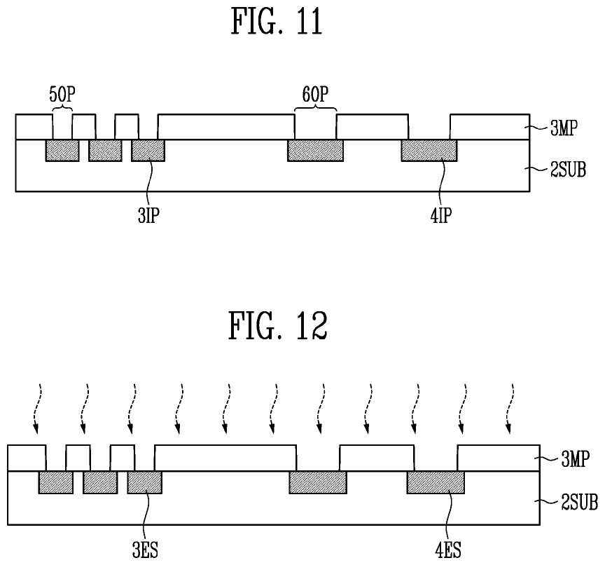

Referring to FIG. 11, a third mask pattern 3MP may be formed on a second substrate 2SUB. The second substrate 2SUB may be a silicon substrate. The third mask pattern 3MP may include fifth openings 5OP and sixth openings 6OP that expose a portion of the second substrate 2SUB. In this example, the width of each of the fifth openings 5OP is smaller than the width of each of the sixth openings 6OP. Thus, the area of the second substrate 2SUB exposed through the fifth openings 5OP is smaller than the area of the second substrate 2SUB exposed through the sixth openings 6OP.

Subsequently, the ion implantation process may be performed to form third ion implantation regions 3IP and fourth ion implantation regions 4IP in the second substrate 2SUB exposed through the fifth openings 5OP and the sixth openings 6OP, respectively. The third ion implantation regions 3IP may be formed in the second substrate 2SUB exposed through the fifth openings 5OP, and the fourth ion implantation regions 4IP may be formed in the second substrate 2SUB exposed through the sixth openings 6OP.

The ion implant process may be performed using ions that may have an etch selectivity different from that of the second substrate 2SUB. For example, the ion implantation process may be performed by implanting nitrogen ions into the second substrate 2SUB exposed through the fifth openings 5OP and the sixth openings 6OP. The third ion implantation regions 3IP and the fourth ion implantation regions 4IP of the second substrate 2SUB into which the nitrogen ions are implanted may become an amorphous silicon nitride layer (SixNy; where x and y are positive integers). The depth and width of the third ion implantation regions 3IP and fourth ion implantation regions 4IP may be adjusted depending on the type of gas supplied into the chamber, the amount of gas, the movement speed of ions, and/or temperature inside the chamber during the ion implantation process.

Referring to FIG. 12, the heat treatment process may be performed to recrystallize the second substrate 2SUB of the third ion implantation regions 3IP and the fourth ion implantation regions 4IP (see FIG. 11). The silicon nitride layers of the third ion implantation regions 3IP and the fourth ion implantation regions 4IP (see FIG. 11) recrystallized by the heat treatment process serve as third etch stop patterns 3ES and fourth etch stop patterns 4ES in this example. For example, the third ion implantation regions 3IP (see FIG. 11) become the third etch stop patterns 3ES, while the fourth ion implantation regions 4IP (see FIG. 11) become the fourth etch stop patterns 4ES.

During the heat treatment process, the ions implanted into the third ion implantation regions 3IP and the fourth ion implantation regions 4IP may diffuse into the second substrate 2SUB, such that the third etch stop patterns 3ES may be larger in size than the third ion implantation regions 3IP, and the fourth etch stop patterns 4ES may also be larger in size than the fourth ion implantation regions 4IP. The sizes of the third etch stop patterns 3ES and the fourth etch stop patterns 4ES may be varied depending on the concentration of ions implanted into the second substrate 2SUB.

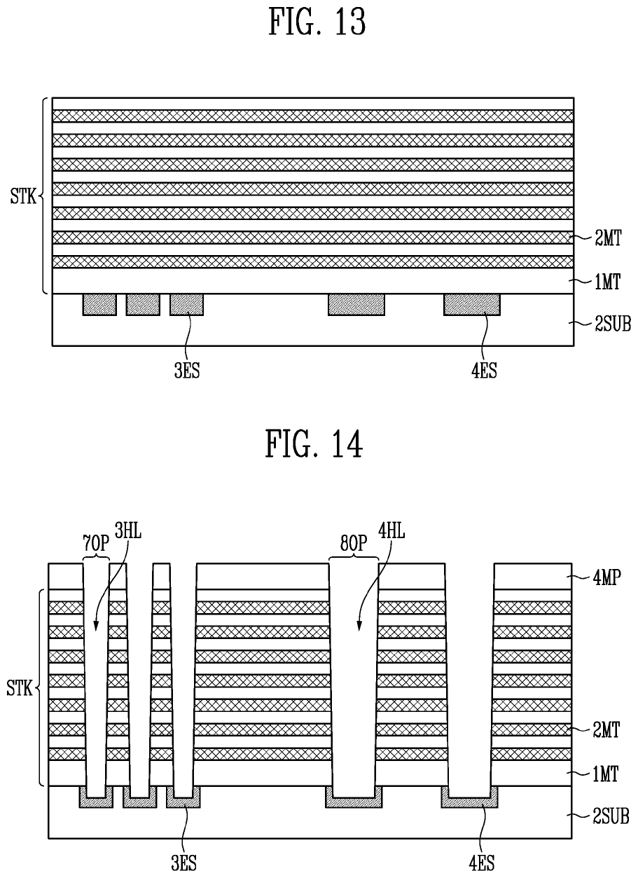

Referring to FIG. 13, a stacked structure STK (which may be referred to as the target structure TGS) including first material layers 1MT and second material layers 2MT may be formed on the second substrate 2SUB including the third etch stop patterns 3ES and the fourth etch stop patterns 4ES. For example, the first material layers 1MT may be oxide layers, while the second material layers 2MT may be nitride layers. The first material layers 1MT and the second material layers and 2MT may be alternately stacked, as shown in the example of FIG. 13. Among the first material layers 1MT, a lowermost first material layer 1MT may be thicker than other first material layers 1MT. As such, etching conditions are changed such that the etch selectivity of the first material layer 1MT is higher than the etch selectivity of the third etch stop patterns 3ES and the fourth etch stop patterns 4ES during a subsequent etching process.

Referring to FIG. 14, a fourth mask pattern 4MP including seventh openings 7OP and eighth openings 8OP may be formed on the stacked structure STK. The fourth mask pattern 4MP may expose a portion of the stacked structure STK through the seventh openings 7OP and the eighth openings 8OP. A width of each of the seventh openings 7OP may be smaller than a width of each of the eighth openings 8OP. Subsequently, the etching process may be performed to form third holes 3HL and fourth holes 4HL in the stacked structure STK exposed through the seventh and eighth openings 7OP and 8OP.

The etching process may be an anisotropic dry etching process. Because the area exposed through the eighth openings 8OP is larger than the area exposed through the seventh openings 7OP during the etching process of the stacked structure STK, the fourth holes 4HL may be formed to be deeper in depth than the third holes 3HL. Thus, the fourth etch stop pattern 4ES may be exposed through the fourth holes 4HL before the third etch stop patterns 3ES are exposed through the third holes 3HL. During the etching process, when components of the third etch stop patterns 3ES and the fourth etch stop patterns 4ES are detected, the conditions of the etching process may be changed such that the etch selectivity of the first material layer 1MT of the target structure is higher than the etch selectivity of the third etch stop patterns 3ES and the fourth etch stop patterns 4ES.

Therefore, while the etching process that forms the third holes 3HL at the target depth is performed, an increase in the depth, of the fourth holes 4HL, beyond the target depth, may be prevented. The etching process may be performed until the third etch stop patterns 3ES and the fourth etch stop patterns 4ES are exposed through the third holes 3HL and the fourth holes 4HL, respectively.

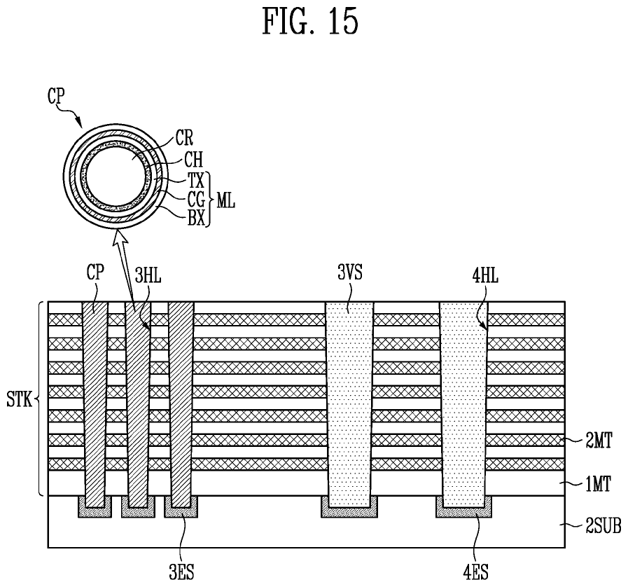

Referring to FIG. 15, cell plugs CP may be formed in the third holes 3HL, and third vertical structures 3VS may be formed in the fourth holes 4HL.

The cell plugs CP may include memory cells and select transistors, for example, as described with respect to FIG. 8 and FIG. 9. For example, each of the cell plugs CP corresponding to the memory cells or the select transistors may include a core pillar CR, a channel layer CH, and a memory layer ML. The memory layer ML may include a tunnel isolation layer TX, a charge trap layer CG, and a blocking layer BX. The core pillar CR may have a cylindrical shape and may be formed comprising an insulating material or conductive material. The channel layer CH may have the shape of a cylinder enclosing the side of the core pillar CR and may be formed of polysilicon. The tunnel isolation layer TX may have the shape of a cylinder enclosing the side of the channel layer CH and may be formed of an oxide layer. The charge trap layer CG may have the shape of a cylinder enclosing the side of the tunnel isolation layer TX and may be formed of a nitride layer. The blocking layer BX may have the shape of a cylinder enclosing the side of the charge trap layer CG and may be formed of an oxide layer.

The third vertical structures 3VS may be support structures or contacts. When the third vertical structures 3VS are the support structures, the third vertical structures 3VS may be formed comprising an insulating material or may be formed comprising the same material as the cell plugs. When the third vertical structures 3VS are formed as the contacts, the third vertical structures 3VS may comprise a conductive material and may further include an insulator enclosing the sides of the conductive material.

Because the depths of the third holes 3HL and fourth holes 4HL are similar to each other due to the placement of the third etch stop patterns 3ES and the fourth etch stop patterns 4ES, the heights of the cell plugs CP and the third vertical structures 3VS formed in the third holes 3HL and the fourth holes 4HL are also similar to each other.

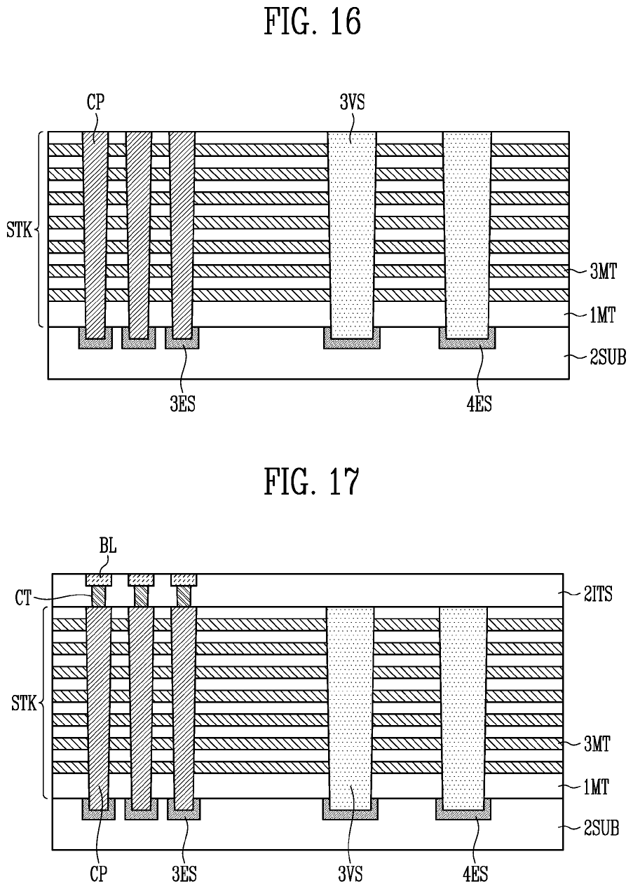

Referring to FIG. 16, the second material layers 2MT (see FIG. 15) are replaced with third material layers 3MT. For example, a slit dividing the memory blocks may be formed, and the second material layers 2MT exposed through the slit may be removed. Subsequently, the third material layers 3MT may be formed in regions where the second material layers 2MT were removed. Because the third material layers 3MT are used as word lines or select lines, third material layers 3MT may be formed of a conductive material. For example, the third material layers 3MT may be formed comprising a metal material such as tungsten (W), molybdenum (Mo), cobalt (Co), and nickel (Ni), or a semiconductor material such as silicon (Si) or polysilicon (Poly-Si).

Referring to FIG. 17, contacts CT, bit lines BL, and a second interlayer insulator 2ITS may be formed on the entire structure including the cell plugs CP and the third vertical structures 3VS. For example, the contacts CT and the bit lines BL may be formed on the cell plugs CP.

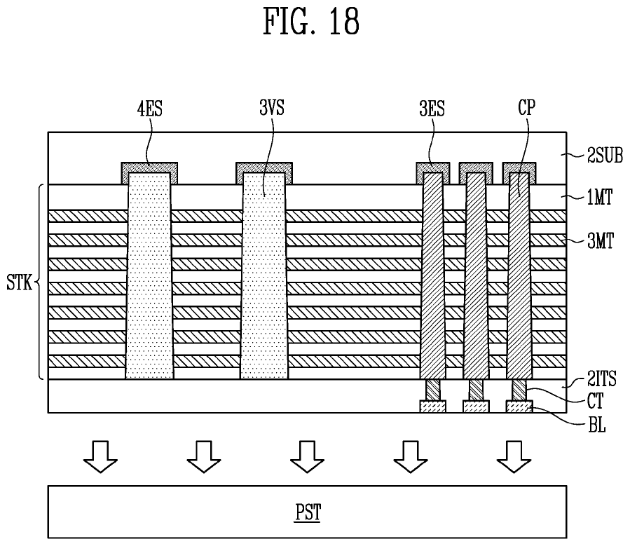

Referring to FIG. 18, the entire structure described with reference to FIG. 17 may optionally be flipped over, in other words, rotated 180 degrees vertically with respect to the drawing perspective or otherwise turned around or over, for ease of further processing. The flipped structure comes into contact with a peripheral structure PST, such as described with reference to FIG. 10. For example, when the entire structure described with reference to FIG. 17 is flipped over, the second substrate 2SUB may be located at the top of the structure with respect to the drawing perspective, and the second interlayer insulator 2ITS and the bit lines BL may be located at the bottom of the flipped structure with respect to the drawing perspective. Although not illustrated in the drawings, the bit lines BL may contact the contacts included in the peripheral structure PST, and the second interlayer insulator 2ITS may contact the first interlayer insulator 1ITS (see FIG. 10) of the peripheral structure PST. The entire structure described with reference to FIG. 17 may be referred to as a processed structure, which has a first end opposite to a second end, where the second substrate 2SUB or underlying structure UDS is disposed at the first end of the processed structure and the second interlayer insulator 2ITS is disposed at the second end of the processed structure in this example.

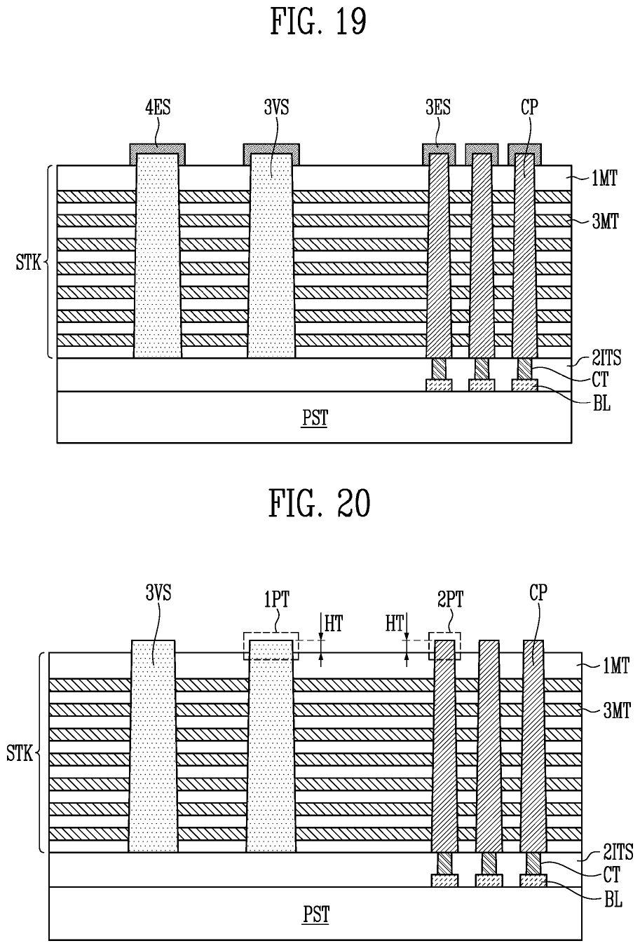

Referring to FIG. 19, the second substrate 2SUB (see FIG. 18) is optionally removed. The second substrate 2SUB may be removed by a wet etching process. The third etch stop patterns 3ES and the fourth etch stop patterns 4ES may remain due to a difference in etch selectivity from the second substrate 2SUB. During the etching process for removing the second substrate 2SUB, the cell plugs CP and the third vertical structures 3VS may be advantageously protected by the third etch stop patterns 3ES and the fourth etch stop patterns 4ES, thus preventing damage to the cell plugs CP and vertical structures 3VS due to the etching process.

Referring to FIG. 20, the third etch stop patterns 3ES and the fourth etch stop patterns 4ES (see FIG. 18) may be removed. For example, the third etch stop patterns 3ES and the fourth etch stop patterns 4ES may be removed by a dry etching process. When the third etch stop patterns 3ES and the fourth etch stop patterns 4ES are removed, portions of the cell plugs CP and the third vertical structures 3VS may protrude from the top of the entire structure with respect to the drawing perspective, for example, the first material layer 1MT. The protruding portions of the third vertical structures 3VS are referred to as first protrusions 1PT, and the protruding portions of the cell plugs CP are referred to as second protrusions 2PT. The first protrusions 1PT and the second protrusions 1PT and 2PT may have the same height HT.

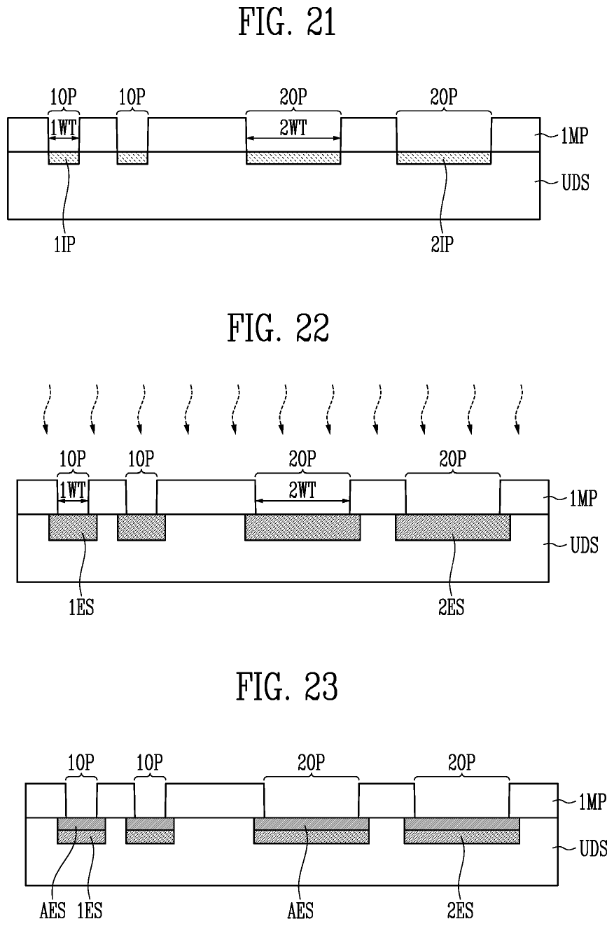

FIG. 21 through FIG. 26 illustrate various views of a memory device formed utilizing a method of manufacturing the memory device according to a second embodiment of the present disclosure.

Referring to FIG. 21, a first mask pattern 1MP may be formed on an underlying structure UDS. The first mask pattern 1MP may include first openings 1OP and second openings 2OP that expose a portion of the underlying structure UDS. The ion implantation process is performed to form first ion implantation regions 1IP and second ion implantation regions 2IP in the underlying structure UDS exposed through the first openings 1OP and the second openings 1OP and 2OP of the first mask pattern 1MP. For example, the ion implantation process may be performed by implanting nitrogen ions into the underlying structure UDS exposed through the first openings 1OP and the second openings 2OP. The first ion implantation regions 1IP and the second ion implantation regions 2IP of the underlying structure UDS into which the nitrogen ions are implanted may become an amorphous silicon nitride layer (SixNy; where x and y are positive integers). Each of the first ion implantation regions 1IP may have a first width 1WT that is the same as the width of each of the first openings 1OP. Each of the second ion implantation regions 2IP may have a second width 2WT that is the same as the width of each of the second openings 2OP.

Referring to FIG. 22, the heat treatment process is performed to recrystallize the underlying structure UDS of the first ion implantation regions 1IP and the second ion implantation regions 2IP (see FIG. 21). The silicon nitride layers of the first ion implantation regions 1IP and the second ion implantation regions 2IP (see FIG. 21) recrystallized by the heat treatment process serve as first etch stop patterns 1ES and second etch stop patterns 2ES. For example, the first ion implantation regions 1IP (see FIG. 3) become the first etch stop patterns 1ES, while the second ion implantation regions 2IP (see FIG. 3) become the second etch stop patterns 2ES.

During the heat treatment process, the ions implanted into the first ion implantation regions 1IP and the second ion implantation regions 2IP may diffuse into the underlying structure UDS, such that the first etch stop patterns 1ES are larger in size than the first ion implantation regions 1IP, and the second etch stop patterns 2ES are larger in size than the second ion implantation regions 2IP. The sizes of the first etch stop patterns 1ES and the second etch stop patterns 2ES may be varied depending on the concentration of ions.

Referring to FIG. 23, portions of the first etch stop patterns 1ES and the second etch stop patterns 2ES exposed through the first openings 1OP and the second openings 2OP of the first mask pattern 1MP may be oxidized to form auxiliary etch stop patterns AES. For example, portions of outer or outermost portions of the first etch stop patterns 1ES and the second etch stop patterns 2ES may be oxidized to form the auxiliary etch stop patterns AES. The auxiliary etch stop patterns AES may be silicon oxide layers (SixOy; where x and y are positive integers). A wet oxidation process or a dry oxidation process may be performed as the oxidation process that forms the auxiliary etch stop patterns AES.

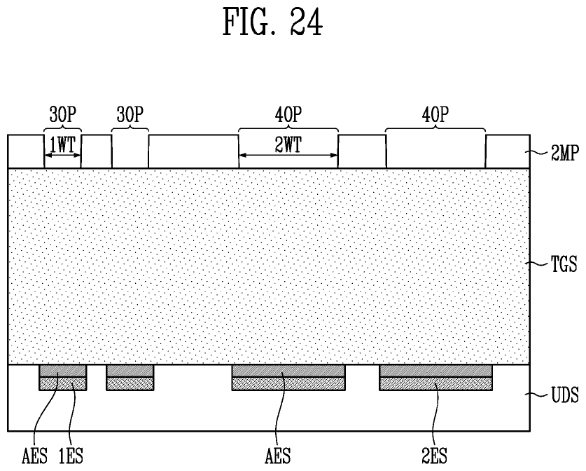

Referring to FIG. 24, the target structure TGS and the second mask pattern 2MP may be sequentially stacked on the underlying structure UDS including the auxiliary etch stop patterns AES. For example, the target structure TGS may be formed of a single layer or multiple layers. In the second embodiment, the type and number of materials forming the target structure TGS are not limited.

The second mask pattern 2MP may be composed of a photoresist pattern or may be composed of a hard mask pattern and a photoresist pattern stacked on the hard mask pattern. For example, the hard mask pattern may be a mask layer formed of carbon. The second mask pattern 2MP may include third openings 3OP and fourth openings 4OP that expose a portion of the target structure TGS.

In the second mask pattern 2MP, each of the third openings 3OP is formed with the first width 1WT, and each of the fourth openings 4OP is formed with the second width 2WT that is greater than the first width 1WT in this example. In this example, the area of the target structure TGS exposed through the third openings 3OP of the second mask pattern 2MP is smaller than the area of the target structure TGS exposed through the fourth openings 4OP.

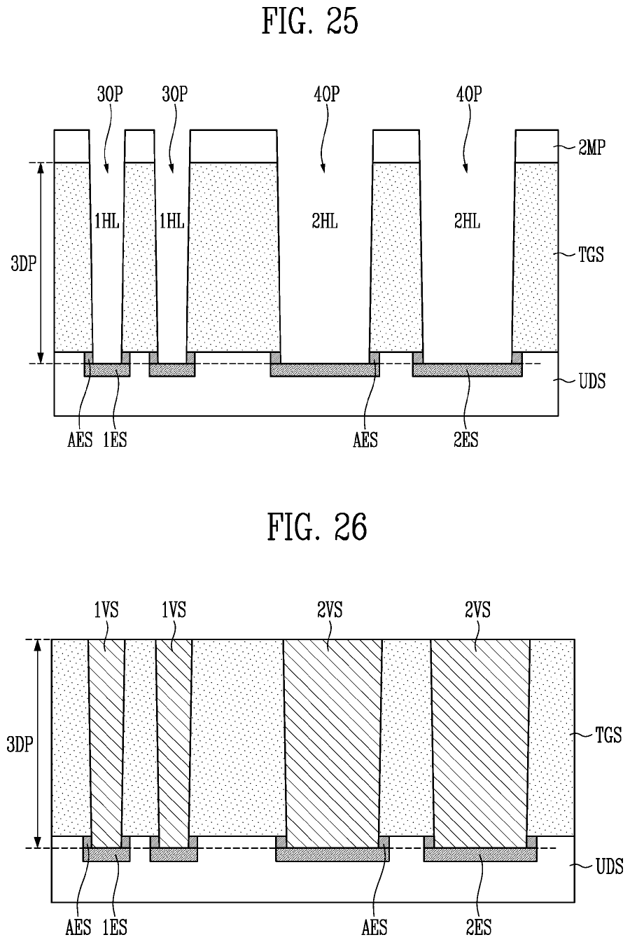

Referring to FIG. 25, the etching process may be performed to form the first holes 1HL and the second holes 2HL in the target structure TGS exposed through the third openings 3OP and the fourth openings 4OP of the second mask pattern 2MP. The etching process may be an anisotropic dry etching process. Because the area exposed through the fourth openings 4OP is larger than the area exposed through the third openings 3OP during the etching process of the target structure TGS, the second holes 2HL may be formed to be deeper in depth than the first holes 1HL, in other words, the second holes 2HL may be formed with a height higher than the height of the first holes 1HL as formed.

Thus, the auxiliary etch stop patterns AES may be exposed through the second holes 2HL before the auxiliary etch stop patterns AES are exposed through the first holes 1HL. Even if the auxiliary etch stop patterns AES are first exposed through the second holes 2HL, the etching process of the second holes 2HL may be suppressed while the etching process that forms the first holes 1HL is performed. Therefore, while the etching process that forms the first holes 1HL to the third depth 3DP, which is the target depth, is performed, an increase in the depth of the second holes 2HL, beyond the target depth, may be prevented. The etching process may be performed until the auxiliary etch stop patterns AES or the first and second etch stop patterns 1ES and 2ES are exposed through the first and second holes 1HL and 2HL. For example, a center part of the auxiliary etch stop patterns AES may be partially or completely removed, leaving an outer perimeter of the auxiliary etch stop patterns AES such as shown in FIG. 25 and FIG. 26.

Referring to FIG. 26, gap-fill layers may be filled in the first holes 1HL and the second holes 2HL to form first vertical structures 1VS and second vertical structures 2VS that contact the first etch stop patterns 1ES and the second etch stop patterns 2ES, respectively. The first vertical structures 1VS and the second vertical structures 2VS may be formed of the same material to provide the same structure or may be formed of different materials to provide different structures. For example, the first vertical structures 1VS may be formed in the first holes 1HL, and the second vertical structures 2VS may be formed in the second holes 2HL. The first vertical structures 1VS and the second vertical structures 2VS may be formed having the third depth 3DP by the first etch stop patterns 1ES and the second etch stop patterns 2ES.

According to the present disclosure, i etch stop patterns are easily formed as well as holes of different widths at the same depth.

What is claimed is:

1. A method of manufacturing a memory device, the method comprising:
forming an ion implantation region in a portion of an outer portion of an underlying structure by implanting ions into the underlying structure;
transforming the ion implantation region into an etch stop pattern;
forming a target structure on the underlying structure including the etch stop pattern; and
performing an etching process to form first holes and second holes in the target structure, wherein a first width of the first holes is different than a second width of the second holes;
wherein the etching process is performed until the etch stop pattern is exposed through the first holes and the second holes.

2. The method according to claim 1, wherein forming the ion implantation region comprises:
forming a mask pattern including openings with different widths on the underlying structure; and
implanting the ions into regions within the underlying structure, which regions are exposed through the openings.

3. The method according to claim 1, wherein the ions are nitrogen ions.

4. The method according to claim 1, wherein the ion implantation region comprises a region with a relatively high ion concentration of ions and a region with a relatively low ion concentration of ions depending on energy of the ion implantation process.

5. The method according to claim 1, wherein a heat treatment process is performed to transform the ion implantation region into the etch stop pattern.

6. The method according to claim 1, further comprising, before forming the target structure, forming an auxiliary etch stop pattern in a portion of an outer portion of the etch stop pattern.

7. The method according to claim 6, wherein the auxiliary etch stop pattern is formed by performing a wet oxidation process or a dry oxidation process.

8. The method according to claim 1, wherein a condition of the etching process is adjusted to increase an etch selectivity of the target structure when a component of the etch stop pattern is detected during the etching process.

9. A method of manufacturing a memory device, the method comprising:
forming an ion implantation region in a portion of an outer portion of a first underlying structure;
performing a heat treatment process for changing the ion implantation region into an etch stop pattern;
alternately stacking first material layers and second material layers on the first underlying structure including the etch stop pattern; and
forming, in the first material layers and the second material layers, a first hole that exposes a first portion of the etch stop pattern, wherein the first hole has a first width, and a second hole that exposes a second portion of the etch stop pattern, wherein the second hole has a second width greater than the first width.

10. The method according to claim 9, wherein, when a first material layer of the first material layers contacts the etch stop pattern of the first underlying structure, where an etch selectivity of the first material layer is greater than the etch selectivity of the etch stop pattern.

11. The method according to claim 9, wherein the ion implantation region is formed by implanting nitrogen ions into the first underlying structure.

12. The method according to claim 11, wherein the etch stop pattern is formed by recrystallizing the ion implantation region of the first underlying structure through the heat treatment process.

13. The method according to claim 9, wherein the etch stop pattern is a silicon nitride layer.

14. The method according to claim 9, further comprising after performing the heat treatment process, changing a portion of an outer portion of the etch stop pattern into an oxide layer.

15. The method according to claim 14, wherein a wet oxidation process is performed to change the portion of the outer portion of the etch stop pattern into the oxide layer.

16. The method according to claim 14, wherein a dry oxidation process is performed to change the portion of the outer portion of the etch stop pattern into the oxide layer.

17. The method according to claim 9, wherein the first underlying structure is a silicon substrate.

18. The method according to claim 9, further comprising, after forming the first holes and the second holes:
forming a cell plug in the first hole;
forming a vertical structure in the second hole;
replacing the second material layers with third material layers, resulting in a processed structure having a first end and a second end opposite the first end, with the first underlying structure disposed at the first end of the processed structure;
bringing the second end of the processed structure into contact with a peripheral structure;
removing a substrate included in the first underlying structure to expose the etch stop pattern; and
removing the etch stop pattern exposed due to removal of the substrate.

19. The method according to claim 18, wherein the peripheral structure comprises a second underlying structure and peripheral circuits formed on the second underlying structure.

20. A memory device comprising:
an underlying structure including a first etch stop pattern and a second etch stop pattern; and
a target structure formed over the underlying structure, wherein a first hole having a first aspect ratio and a second hole having a second aspect ratio less than the first aspect ratio are formed in the target structure, wherein the first etch stop pattern is exposed by the first hole and the second etch stop pattern is exposed by the second hole;
wherein the first etch stop pattern and the second etch stop pattern include etching stop ions for stopping an etching process; and
wherein the second etch stop pattern includes a region having a high concentration of etching stop ions and a region having a low concentration of etching stop ions.

21. The memory device of claim 20, wherein concentration of the etching stop ions in the first etch stop pattern is uniform.

22. The memory device of claim 20, wherein the etching stop ions include nitrogen ions.

23. The memory device of claim 20, wherein each of the first hole and the second hole has a circular, elliptical, or line shape.

24. A method of manufacturing a memory device, the method comprising:
forming a target structure over an underlying structure;
forming a mask pattern over the target structure;
implanting etching stop ions into the underlying structure through the target structure using the mask patterns to form a first etch stop pattern and a second etch stop pattern; and
etching the target structure using the mask pattern until the first etch stop pattern is exposed to form a first hole with a first aspect ratio and etching the target structure until the second etch stop pattern is exposed to form a second hole with a second aspect ratio less than the first aspect ratio;
wherein, when the etch stop ions are implanted, the second etch stop pattern includes a region having a high concentration of etching stop ions and a region having a low concentration of etching stop ions.
